(19) United States
(12) Patent Application Publication
(10) Pub. No.: US 2025/0216798 A1
(43) Pub. Date: Jul. 3, 2025

(54) METHOD AND APPARATUS FOR DETERMINING PHOTORESIST MODEL FOR GENERATING PHOTORESIST PATTERN

(71) Applicant: Tencent Technology (Shenzhen ) Company Limited, Shenzhen (CN)

(72) Inventors: Xingyu MA, Shenzhen (CN); Shaogang Hao, Shenzhen (CN); Shengyu Zhang, Shenzhen (CN)

(73) Assignee: Tencent Technology ( Shenzhen) Company Limited, Shenzhen (CN)

(21) Appl. No.: 19/083,786

(22) Filed: Mar. 19, 2025

Related U.S. Application Data
(63) Continuation of application No. PCT/CN2023/131292, filed on Nov. 13, 2023.

(30) Foreign Application Priority Data
Mar. 28, 2023 (CN) 202310371665.2

(51) Int. Cl. G03F 7/00; G06F 17/18; G06F 30/27

(52) U.S. Cl. CPC G03F 7/705; G06F 17/18; G06F 30/27

(57) ABSTRACT

A method and an apparatus for determining a photoresist model used for generating a photoresist pattern. The method includes: obtaining a plurality of first parameter groups from a first parameter group set of a photoresist model; fitting the photoresist model based on the plurality of first parameter groups and a plurality of reference photoresist pattern matrixes to obtain a plurality of coefficients; predicting expected values of a plurality of second parameter groups based on the photoresist model with the determined coefficients and errors between predicted photoresist pattern matrixes of first parameter groups and the reference photoresist pattern matrixes, and adding a second parameter group with the expected value to obtain an updated first parameter group set; and respectively assigning a plurality of candidate values in the parameter group having a minimum error in the updated first parameter group set to a plurality of parameters in the photoresist model.

### RELATED APPLICATION

This application is a continuation of and claims the benefit of priority to PCT/CN2023/131292 filed on Nov. 13, 2023, which is based on and claims the benefit of priority to Chinese Patent Application No. 202310371665.2, entitled “METHOD AND APPARATUS FOR DETERMINING PHOTORESIST MODEL FOR GENERATING PHOTORESIST PATTERN” and filed with the China National Intellectual Property Administration on Mar. 28, 2023, both of which are incorporated herein by reference.

### FIELD OF THE TECHNOLOGY

This application relates to the field of photolithography modeling technologies, and in particular, to a method and an apparatus for determining a photoresist model for generating a photoresist pattern.

### BACKGROUND OF THE DISCLOSURE

A photolithography process is a most core, most complex, and most cost process in an integrated circuit manufacturing process. In the photolithography process, a pattern on a mask is replicated to a photoresist applied to a surface of a silicon wafer in a mode of optical exposure, and then the pattern is further transferred to the silicon wafer through processes such as developing and etching to obtain a photoresist pattern.

### SUMMARY

Exemplary embodiments of this disclosure provide a method and an apparatus for determining a photoresist model for generating a photoresist pattern, which improves accuracy of the photoresist model while ensuring optimization efficiency. Technical solutions are as follows:

According to an aspect, a method for determining a photoresist model for generating a photoresist pattern is provided. The method includes: obtaining a plurality of first parameter groups in a first parameter group set of a photoresist model in any iteration process of training the photoresist model, the photoresist model including a plurality of photoresist items configured for generating a photoresist pattern, each photoresist item being configured for describing a plurality of reaction processes of a photoresist, each photoresist item including a coefficient and a parameter configured for describing the reaction process, and the first parameter group set being a subset of a candidate parameter group set; fitting the photoresist model based on the plurality of first parameter groups and a plurality of reference photoresist pattern matrixes to obtain coefficients of the plurality of photoresist items in the photoresist model; determining predicted photoresist pattern matrixes of the plurality of first parameter groups based on the photoresist model with the determined coefficients and the plurality of first parameter groups, predicting expected values of a plurality of second parameter groups in the candidate parameter group set based on the plurality of first parameter groups and errors respectively corresponding to the plurality of first parameter groups, and adding the second parameter group with the expected value satisfying a target condition in the plurality of second parameter groups to the first parameter group set to obtain an updated first parameter group set, the expected values being configured for indicating degree of optimization of the second parameter group for the photoresist model, the error corresponding to each parameter group being a difference between the predicted photoresist pattern matrix of the parameter group and the plurality of reference photoresist pattern matrixes, and the second parameter group being a parameter group other than the first parameter group in the candidate parameter group set; and respectively assigning, in a case that a current iteration process satisfies an iteration stop condition, a plurality of candidate values in the parameter group having a minimum error in the updated first parameter group set to a plurality of parameters in the photoresist model.

According to another aspect, an apparatus for determining a photoresist model for generating a photoresist pattern is provided. The apparatus includes: an obtaining module, configured to obtain a plurality of first parameter groups in a first parameter group set of a photoresist model in any iteration process of training the photoresist model, the photoresist model including a plurality of photoresist items configured for generating a photoresist pattern, each photoresist item being configured for describing a plurality of reaction processes of a photoresist, each photoresist item including a coefficient and a parameter configured for describing the reaction process, and the first parameter group set being a subset of a candidate parameter group set; a fitting module, configure to fit the photoresist model based on the plurality of first parameter groups and a plurality of reference photoresist pattern matrixes to obtain coefficients of the plurality of photoresist items in the photoresist model; a determining module, configured determine predicted photoresist pattern matrixes of the plurality of first parameter groups based on the photoresist model with the determined coefficients and the plurality of first parameter groups, predict expected values of a plurality of second parameter groups in the candidate parameter group set based on the plurality of first parameter groups and errors respectively corresponding to the plurality of first parameter groups, and add a second parameter group with the expected value satisfying a target condition in the plurality of second parameter groups to the first parameter group set to obtain an updated first parameter group set, the expected values being configured for indicating degree of optimization of the second parameter group for the photoresist model, the error corresponding to each parameter group being a difference between the predicted photoresist pattern matrix of the parameter group and the plurality of reference photoresist pattern matrixes, and the second parameter group being a parameter group other than the first parameter group in the candidate parameter group set; and an assignment module, configured to respectively assign, in a case that a current iteration process satisfies an iteration stop condition, a plurality of candidate values in the parameter group having a minimum error in the updated first parameter group set to a plurality of parameters in the photoresist model.

In some exemplary embodiments, the determining module is configured to: establish a Gaussian process model based on the plurality of first parameter groups and the errors respectively corresponding to the plurality of first parameter groups to obtain a mean function and a kernel function in the Gaussian process model, the mean function and the kernel function being configured to predict, based on the parameter group, an error corresponding to the parameter group; determining, for each second parameter group based on the mean function and the kernel function, a mean value and a kernel function value that correspond to the second parameter group; and determine the expected value corresponding to the second parameter group based on the mean value and the kernel function value that correspond to the second parameter group.

In some exemplary embodiments, the determining module is configured to: add a second parameter group with the expected value sorted in a first target digit in the plurality of second parameter groups to the first parameter group set.

In some exemplary embodiments, the determining module is configured to: add a second parameter group with the expected value greater than a preset expected value in the plurality of second parameter groups to the first parameter group set.

In some exemplary embodiments, the obtaining module is configured to: cluster the plurality of parameter groups in the candidate parameter group set to obtain a plurality of categories, and add a parameter group closest to a cluster center of the category in each category to the first parameter group set to obtain the first parameter group set in the first iteration process.

In some exemplary embodiments, the fitting module is configured to: perform least square fitting on the photoresist model based on the plurality of first parameter groups and the plurality of reference photoresist pattern matrixes to obtain the coefficients of the plurality of photoresist items.

In some exemplary embodiments, the apparatus further includes: a difference determining module, configured determine, for each first parameter group in the first parameter group set, differences between the predicted photoresist pattern matrix of the first parameter group and the plurality of reference photoresist pattern matrixes; and an error determining module, configured to use a root-mean-square error among a plurality of differences as the error corresponding to the first parameter group, the plurality of differences being differences between the predicted photoresist pattern matrix of the first parameter group and the plurality of reference photoresist pattern matrixes.

In some exemplary embodiments, the apparatus further includes: a sampling module, configured to sample from parameter space of a plurality of parameters based on value ranges of the plurality of parameters of the photoresist model to obtain the candidate parameter group set.

In some exemplary embodiments, the apparatus further includes: a comparison module, configured to: compare a minimum error corresponding to a parameter group in the second parameter group set with a minimum error corresponding to a parameter group in the third parameter group set, update value ranges of the plurality of parameters in the parameter space based on a comparison result, re-determine a candidate parameter group set based on the updated value ranges, and re-iteratively determine a photoresist model based on the re-determined candidate parameter group set, the second parameter group set being a first parameter group set in a first iteration process, and the third parameter group set being a first parameter group set obtained by iterating the first parameter group set for a plurality of times; and an iteration module, configured to iteratively perform operations of comparing a minimum error corresponding to a parameter group in the second parameter group set with a minimum error corresponding to a parameter group in a third parameter group set, updating the value range of the plurality of parameters in the parameter space based on a comparison result, re-determining a candidate parameter group set based on updated value ranges, and re-iteratively determining the photoresist model based on the re-determined candidate parameter group set, and use, in a case that any iteration process satisfies a preset condition, the photoresist model obtained in a current iteration as a target photoresist model.

In some exemplary embodiments, the comparison module is configured to: reduce, in a case that the minimum error corresponding to the parameter group in the second parameter group set is less than or equal to the minimum error corresponding to the parameter group in the third parameter group set, the value ranges of the plurality of parameters in the parameter space according to a preset proportion by using the parameter group corresponding to the minimum error in the second parameter group set as a center; and increase, in a case that the minimum error corresponding to the parameter group in the second parameter group set is greater than the minimum error corresponding to the parameter group in the third parameter group set, the value ranges of the plurality of parameters in the parameter space according to a preset proportion by using the parameter group corresponding to the minimum error in the third parameter group set as a center.

According to another aspect, a computer device is provided. The computer device includes a processor and a memory. The memory is configured to store at least one computer program, and the at least one computer program is loaded and executed by the processor to perform the method for determining a photoresist model for generating a photoresist pattern in the exemplary embodiments of this disclosure.

According to another aspect, a computer-readable storage medium is provided. The computer-readable storage medium stores at least one computer program. The at least one computer program is loaded and executed by a processor to implement the method for determining a photoresist model for generating a photoresist pattern in the exemplary embodiments of this disclosure.

According to another aspect, a computer program product is provided. The computer program product is stored in a computer-readable storage medium. A processor of a computer device reads the computer program from the computer-readable storage medium, and the processor executes the computer program, to enable the computer device to perform the method for determining a photoresist model for generating a photoresist pattern according to any of the foregoing implementations.

The exemplary embodiments of this disclosure provide a method for determining a photoresist model for generating a photoresist pattern. In the method, a predicted photoresist pattern matrix of an existing parameter group in a first parameter group set is determined through the photoresist model, and then degree of optimization of the second parameter group for the photoresist model is predicted based on an error between the predicted photoresist pattern matrix and a reference photoresist pattern matrix, so that a parameter group having good optimization degree in the second parameter groups can be selected to be added to the first parameter group set. According to the method, the first parameter group set is determined iteratively, and in a case that a data volume in the first parameter group set is ensured, a parameter group which can effectively optimize a photoresist model can be found from the first parameter group set, thereby obtaining the photoresist model that can accurately predict a photoresist pattern. In addition, according to the method, a coefficient of the photoresist model is obtained by fitting the parameter group and the reference photoresist pattern, that is, the parameter and the coefficient of the photoresist model are optimized collaboratively, thereby improving accuracy of the photoresist model while ensuring optimization efficiency.

### BRIEF DESCRIPTION OF THE DRAWINGS

To describe technical solutions in exemplary embodiments of this disclosure more clearly, the following briefly introduces accompanying drawings required for descriptions in the exemplary embodiments.

FIG. 1 is a schematic diagram of an implementation environment according to an exemplary embodiment of this disclosure.

FIG. 2 is a flowchart of a method for determining a photoresist model for generating a photoresist pattern according to an exemplary embodiment of this disclosure.

FIG. 3 is a flowchart of another method for determining a photoresist model for generating a photoresist pattern according to an exemplary embodiment of this disclosure.

FIG. 4 is a flowchart of another method for determining a photoresist model for generating a photoresist pattern according to an exemplary embodiment of this disclosure.

FIG. 5 is a flowchart of another method for determining a photoresist model for generating a photoresist pattern according to an exemplary embodiment of this disclosure.

FIG. 6 is a schematic diagram of an error of a photoresist pattern matrix according to an exemplary embodiment of this disclosure.

FIG. 7 is a comparison diagram between a predicted photoresist pattern and a reference photoresist pattern according to an exemplary embodiment of this disclosure.

FIG. 8 is a block diagram of an apparatus for determining a photoresist model for generating a photoresist pattern according to an exemplary embodiment of this disclosure.

FIG. 9 is a block diagram of a terminal according to an exemplary embodiment of this disclosure.

FIG. 10 is a block diagram of a server according to an exemplary embodiment of this disclosure.

### DESCRIPTION OF EMBODIMENTS

To make objectives, technical solutions, and advantages of this disclosure clearer, the following further describes implementations of this disclosure in detail with reference to accompanying drawings.

In this disclosure, terms “first”, “second”, and the like are configured for distinguishing between same items or similar items that have basically same actions and functions. “First”, “second”, and “nth” do not have logical or time sequence dependency, and a number and an execution sequence are not limited either.

In this disclosure, a term “at least one” refers to one or more, and “a plurality of” refers to two or more.

Information (including, but not limited to, user device information, user personal information, the like), data (including, but not limited to, data configured for analyzing, data configured for storage, data configured for displaying, and the like), and signals involved in this disclosure are all authorized by a user or all parties, and collection, use, and processing of relevant data have to comply with relevant laws, regulations, and standards of relevant countries and regions. For example, parameter group and the like involved in this disclosure are obtained under full authorization.

A photolithography process can be described by using a photoresist model. The photoresist model describes a process in which photos in an optical latent image excite a photoresist to generate a series of photochemical reaction, and after baking and developing processes, a photoresist pattern is finally left.

In a development process of the photographing process, new photographing technologies and photoresists always appear, and parameters in an original photoresist model are no longer applicable to the new photographing technologies and photoresists.

Therefore, the parameters in the photoresist model need to be optimized to obtain a new photoresist model with high accuracy.

The following introduces an implementation environment involved in this disclosure.

A method for determining a photoresist model for generating a photoresist pattern according to this exemplary embodiment of this disclosure can be performed by a computer device. The computer device can be a server or a terminal. The following introduces a schematic diagram of an implementation environment of a method for determining a photoresist model for generating a photoresist pattern according to this exemplary embodiment of this disclosure. FIG. 1 is a schematic diagram of an implementation environment a method for determining a photoresist model for generating a photoresist pattern according to an exemplary embodiment of this disclosure. The implementation environment includes a terminal 101 and a server 102. The terminal 101 and the server 102 can be directly or indirectly connected in a wired or wireless communication protocol, which is not limited in this disclosure. In some exemplary embodiments, a target application for performing a photolithography process is installed on the terminal 101, the server 102 is a background server of the target application, and the server 102 is configured to train a photoresist model to which the photographing process is applied. The terminal 101 is embedded into the photoresist model, and is configured to predict a photoresist pattern based on the photoresist model; or the terminal 101 predicts a photoresist pattern through the photoresist model on the server 102.

In some exemplary embodiments, the terminal 101 can be a smartphone, a tablet computer, a laptop computer, a desktop computer, a smart voice interaction device, a smart home appliance, a vehicle terminal, an aircraft, a virtual reality (VR) apparatus, an augmented reality (AR) apparatus, or the like, but is not limited thereto. In some exemplary embodiments, the server 102 can be an independent server, or can be a server cluster composed of a plurality of servers or a distributed system, or can be a cloud server that provides basic cloud computing services such as a cloud service, a cloud database, cloud computing, a cloud function, cloud storage, a network service, cloud communication, a middleware service, a domain name service, a security service, a content delivery network (CDN), a big data platform, and an artificial intelligence (AI) platform. In some exemplary embodiments, the server 102 is responsible for primary computing work, and the terminal 101 is responsible for secondary computing work; or the server 102 is responsible for secondary computing work, and the terminal 101 is responsible for primary computing work; or a distributed computing architecture may be used between the server 102 and the terminal 101 for collaborative computing.

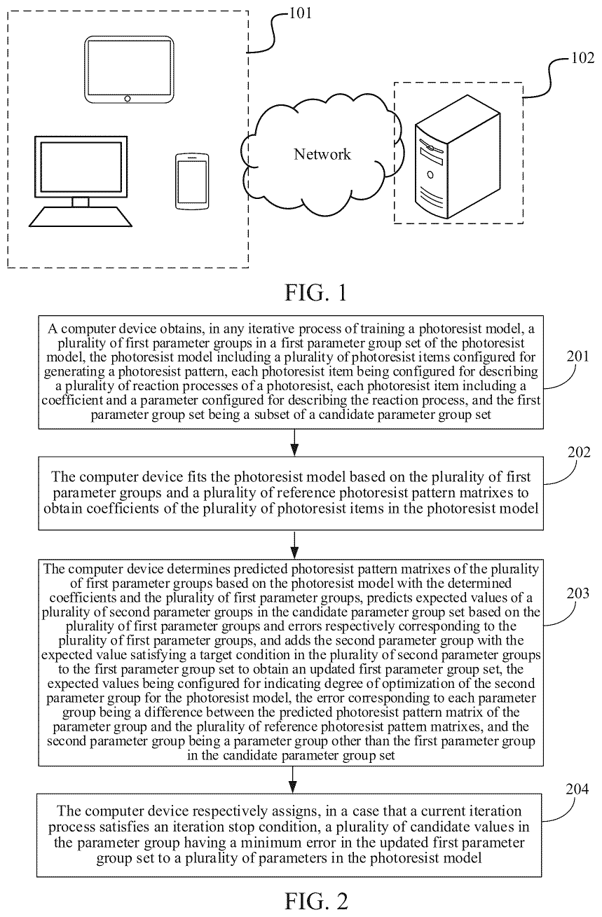

FIG. 2 is a flowchart of a method for determining a photoresist model for generating a photoresist pattern according to an exemplary embodiment of this disclosure. The method is performed by a computer device. The method includes the following operations.

201: A computer device obtains, in any iterative process of training a photoresist model, a plurality of first parameter groups in a first parameter group set of the photoresist model, the photoresist model including a plurality of photoresist items configured for generating a photoresist pattern, each photoresist item being configured for describing a plurality of reaction processes of a photoresist, each photoresist item including a coefficient and a parameter configured for describing the reaction process, and the first parameter group set being a subset of a candidate parameter group set.

In this exemplary embodiment of this disclosure, the photoresist model includes a plurality of photoresist items. The plurality of photoresist items are configured for describing the plurality of reaction processes of the photoresist. The reaction processes are processes of physical reaction or chemical reaction. For example, the physical reaction or the chemical reaction includes molecular diffusion, acid-base neutralization reaction, or the like. The plurality of parameters of the photoresist model are parameters configured for describing the reaction process in the plurality of photoresist items, and each photoresist item has a coefficient. In this exemplary embodiment of this disclosure, the photoresist model is configured for predicting the photoresist pattern based on a given light intensity distribution.

202: The computer device fits the photoresist model based on the plurality of first parameter groups and a plurality of reference photoresist pattern matrixes to obtain coefficients of the plurality of photoresist items in the photoresist model.

In this exemplary embodiment of this disclosure, the reference photoresist pattern matrix is obtained based on experimental measurement data, the reference photoresist pattern matrix is configured for describing a reference photoresist pattern, and a plurality of elements in the reference photoresist pattern matrix respectively represent pixel values at a plurality of pixel positions in the reference photoresist pattern. The reference photoresist pattern is an actual exposure pattern on a wafer, that is, the reference photoresist pattern is a photoresist pattern that is expected to be obtained through the photoresist model.

In this exemplary embodiment of this disclosure, that the computer device fits the photoresist model based on the plurality of first parameter groups and a plurality of reference photoresist pattern matrixes refers to that: the plurality of first parameter groups and the plurality of reference photoresist pattern matrixes are combined pairwise to obtain a plurality of known quantity arrays, and each known quantity array includes one first parameter group and one reference photoresist pattern matrix. The plurality of known quantity arrays are respectively substituted into the photoresist model to fit a plurality of unknown quantities in the photoresist model, that is, coefficients of a plurality of photoresist models.

203: The computer device determines predicted photoresist pattern matrixes of the plurality of first parameter groups based on the photoresist model with the determined coefficients and the plurality of first parameter groups, predicts expected values of a plurality of second parameter groups in the candidate parameter group set based on the plurality of first parameter groups and errors respectively corresponding to the plurality of first parameter groups, and adds a second parameter group with the expected value satisfying a target condition in the plurality of second parameter groups to the first parameter group set to obtain an updated first parameter group set, the expected value being configured for indicating degree of optimization of the second parameter group for the photoresist model, the error corresponding to each parameter group being a difference between the predicted photoresist pattern matrix of the parameter group and the plurality of reference photoresist pattern matrixes, and the second parameter group being a parameter group in the candidate parameter group set other than the first parameter group.

In this exemplary embodiment of this disclosure, the predicted photoresist pattern matrix is configured for describing the predicted photoresist pattern, and the plurality of elements in the predicted photoresist pattern respectively represent pixel values at a plurality of pixel positions in the predicted photoresist pattern. The updated first parameter group set is a first parameter group set used in a next iteration process.

204: The computer device respectively assigns, in a case that a current iteration process satisfies an iteration stop condition, a plurality of candidate values in the parameter group having a minimum error in the updated first parameter group set to a plurality of parameters in the photoresist model.

In this exemplary embodiment of this disclosure, the iteration stop condition is that a number of iterations reaches a preset number of times, or that an error corresponding to the parameter group having the minimum error reaches a preset error. This is not specifically limited herein. The preset number of times and the preset error can be set and modified as required. The computer device iteratively performs the foregoing operations 201 to 203, and obtains an optimal parameter group by continuously iterating the first parameter group set, to obtain a photoresist model with high accuracy.

In this exemplary embodiment of this disclosure, the computer device re-performs operations 202 to 203 based on the first parameter group set obtained in the current iteration, determines the parameter group corresponding to the minimum error in the first parameter group set obtained in the current iteration, and respectively assigns the plurality of candidate values in the parameter group to the plurality of parameters in the photoresist model with the determined coefficients in operation 202, that is, a process of determining the photoresist model is implemented.

The exemplary embodiments of this disclosure provide a method for determining a photoresist model for generating a photoresist pattern. In the method, a predicted photoresist pattern matrix of an existing parameter group in a first parameter group set is determined through the photoresist model, and then degree of optimization of the second parameter group for the photoresist model is predicted based on an error between the predicted photoresist pattern matrix and a reference photoresist pattern matrix, so that a second parameter group having good optimization degree in the plurality of second parameter groups can be selected to be added to the first parameter group set. According to the method, the first parameter group set is updated iteratively, and in a case that a data volume in the first parameter group set is ensured, a parameter group which can effectively optimize a photoresist model can be found from the first parameter group set, thereby obtaining the photoresist model that can accurately predict a photoresist pattern. In addition, according to the method, a coefficient of the photoresist model is obtained by fitting the parameter group and the reference photoresist pattern, that is, the parameter and the coefficient of the photoresist model are optimized collaboratively, thereby improving accuracy of the photoresist model while ensuring optimization efficiency.

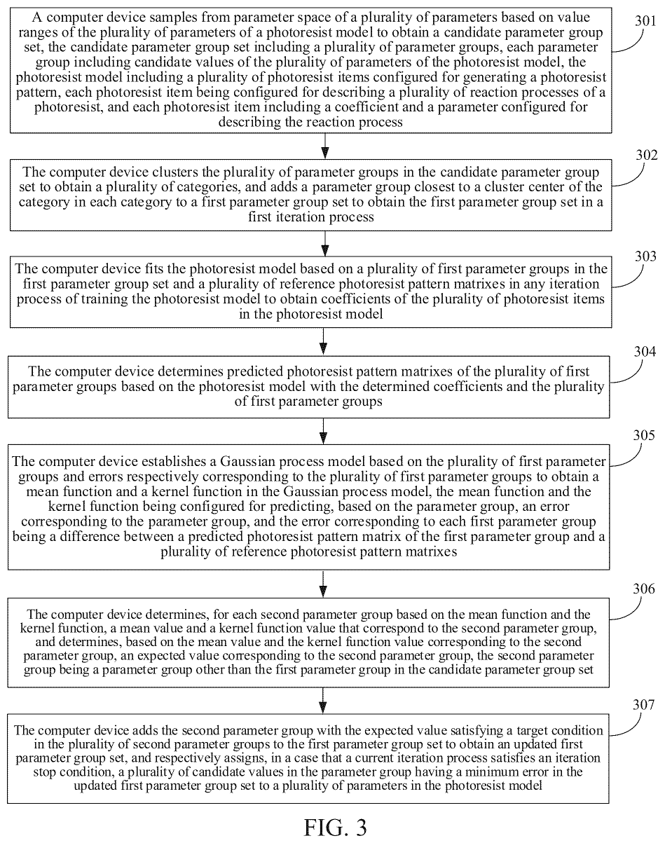

FIG. 2 is a basic process of determining a photoresist model. The process of determining the photoresist model is further described below based on FIG. 3. FIG. 3 is a flowchart of a method for determining a photoresist model for generating a photoresist pattern according to an exemplary embodiment of this disclosure. The method is performed by a computer device. The method includes the following operations.

301: A computer device samples from parameter space of a plurality of parameters based on value ranges of the plurality of parameters of a photoresist model to obtain a candidate parameter group set, the candidate parameter group set including a plurality of parameter groups, each parameter group including candidate values of the plurality of parameters of the photoresist model, the photoresist model including a plurality of photoresist items configured for generating a photoresist pattern, each photoresist item being configured for describing a plurality of reaction processes of a photoresist, and each photoresist item including a coefficient and a parameter configured for describing the reaction process.

In this exemplary embodiment of this disclosure, the computer device first obtains a framework of the photoresist model. Optionally, the framework of the photoresist model is a mathematical formula framework, for example, referring to the following formula (1).

$$RI = {α}_{1} conv ( max ( I - {t}_{1} , 0 ) , G ( {δ}_{1} ) ) + {α}_{2} conv ( max ( {t}_{2} - I , 0 ) , G ( {δ}_{2} ) ) + {α}_{3} conv ( I , G ( {δ}_{3} ) ) + {α}_{4} conv ( {I}_{x}^{2} + {I}_{y}^{2} , G ( {δ}_{4} ) ) ; \qquad ( 1 )$$

where RI represents a matrix output by the photoresist model, each of conv(max(I−t₁, 0), G(δ₁)), conv(max(t₂−I, 0), G(δ₂)), conv(I, G(δ₃)), and conv (Iₓ²+I_{y}², G(δ₄)) represents one photoresist item, and each of α₁, α₂, α₃, and α₄ represents a coefficient of each photoresist item. Each of δ₁ δ₂, δ₃, and δ₄ represents a standard deviation of a Gaussian distribution function G in a photoresist item, that is, a parameter in the photoresist item. Each of t₁ and t₂ represents a threshold of a truncation function max (a maximum value) in a photoresist item, that is, a parameter in the photoresist item, δ₁, δ₂, δ₃, δ₄, t₁, and t₂ are the plurality of parameters to be determined in the photoresist model. In some exemplary embodiments, the plurality of parameters have initial values and initial value ranges, and the plurality of parameters are to be optimized. I represents a light intensity distribution, that is, a distribution of light of a photographing machine on a photoresist on a wafer, the light intensity distribution is usually obtained through calculation of an optical model or experimental measurement. Each of Iₓ² and I_{y}² represents a first-order partial derivative of the light intensity distribution along an X axis and a Y axis, and conv represents a convolution operation.

A plurality of elements in the matrix output by the photoresist model respectively represent pixel values at a plurality of pixel positions in the photoresist pattern. The computer device performs binarization processing on the matrix output by the photoresist model through the following formula (2) to obtain a predicted photoresist pattern matrix.

$$R = \{ \begin{matrix}1 , & RI \geq t \\ 0 , & RI < t\end{matrix} ; \qquad ( 2 )$$

where R represents the predicted photoresist pattern matrix, and RI represents a matrix output by the photoresist model, and t indicates a pixel threshold. Through the formula (2), an element with a corresponding pixel value greater than or equal to the pixel threshold in the matrix output by the photoresist model is assigned to 1, and an element with a corresponding pixel value less than the pixel threshold is assigned to 0.

In this exemplary embodiment of this disclosure, the parameter space is multidimensional parameter space, and can cover value ranges of the plurality of parameters. The value ranges of the plurality of parameters may be the same or different. This is not specifically limited herein. For example, if the photoresist model includes two parameters, the parameter space is a two-dimensional parameter space. Optionally, the value ranges of the two parameters are respectively [0, 1] and [2, 3], and correspondingly, the value range covered by the parameter space in one dimension is not less than [0, 1], and the value range covered by the parameter space in the other dimension is not less than [2, 3].

In this exemplary embodiment of this disclosure, the computer device can perform sampling in the parameter space in a Latin hypercubic sampling mode, or can perform sampling in the parameter space in a random sampling mode. In this exemplary embodiment of this disclosure, an example in which sampling is performed in the Latin hypercube sampling mode is used for description.

In a process of sampling in a Latin hypercubic sampling mode, the computer device selects L sample points for each dimension in the parameter space with a value dimension of K, and divides values of the dimension into L intervals that have a same value length and that do not overlap with each other. A sample point is randomly extracted from each interval, and then the sample points randomly extracted in the plurality of dimensions are cross-combined to obtain the plurality of parameter groups in the candidate parameter group set, where both K and L are integers greater than 0, and K represents a dimension of the plurality of parameters. In this exemplary embodiment of this disclosure, sampling is performed based on the Latin hypercube sampling mode. Compared with random sampling, samples obtained by sampling are more evenly distributed, ensuring comprehensiveness of the sampled samples.

302: The computer device clusters the plurality of parameter groups in the candidate parameter group set to obtain a plurality of categories, and adds a parameter group closest to a cluster center of the category in each category to the first parameter group set to obtain the first parameter group set in the first iteration process.

In some exemplary embodiments, the computer device performs clustering based on a K-means clustering algorithm. The computer device inputs the plurality of parameter groups in the candidate parameter group set into the K-means algorithm, and specifies a number N of cluster centers, where N is an integer greater than 1. A principle of the K-means algorithm is to divide data into N categories according to a Euclidean space distance between the data, data points within a category are connected together as much as possible, and a distance between the data points between the categories is as large as possible. That is, the K-means algorithm minimizes a square error by constantly changing a position of the cluster center. For example, refer to the following formula (3).

$$error = {\sum }_{i = 1}^{N} {\sum }_{x ∈ {C}_{i}} {\vert x - {μ}_{i} \vert}^{2} , {μ}_{i} = \frac{1}{\vert {C}_{i} \vert} {\sum }_{x ∈ {C}_{i}} x ; \qquad ( 3 )$$

where N represents a number of cluster centers, x represents a parameter group in the candidate parameter group set, i represents an i^{th} category, and i is an integer greater than 1, μᵢ represents the cluster center of an i category, C₁ represents a number of data samples in the i^{th} category, and error represents the square error. When the cluster centers of N categories do not change any longer, that is, the square error converges to a minimum, the K-means algorithm outputs N optimal cluster centers and a category where each parameter group is located, and the parameter group closest to the cluster center of the category in each category is added to the first parameter group set to obtain the first parameter group set in the first iteration process.

In some other exemplary embodiments, the computer device can further add a first target number of parameter groups closest to the cluster center of the category in each category to the first parameter group set to increase a data volume of the parameter groups in the first parameter group set.

In this exemplary embodiment of this disclosure, the first parameter group set in the first iteration process is obtained based on the foregoing operation 302. In this exemplary embodiment, the parameter group closest to the cluster center in each category is selected to be added to the first parameter group set, so that the parameter group in the first parameter group set has good representativeness and has high accuracy. The foregoing operation 302 is merely an optional implementation of obtaining the first parameter group set in the first iteration process. In this exemplary embodiment of this disclosure, the first parameter group set can alternatively be obtained in another optional implementation. This is not specifically limited herein. For example, the plurality of parameter groups are randomly selected from the candidate parameter group set to be added to the first parameter group set to obtain the first parameter group set in the first iteration process.

In this exemplary embodiment of this disclosure, a first parameter group set used in any iteration process other than the first parameter group set in the first iteration process is obtained through the following operations 303 to 307. The computer device iteratively performs the following operations 303 to 307 until any iteration process reaches an iteration stop condition.

303: The computer device fits the photoresist model based on a plurality of first parameter groups in the first parameter group set and a plurality of reference photoresist pattern matrixes in any iteration process of training the photoresist model to obtain coefficients of the plurality of photoresist items in the photoresist model.

In some exemplary embodiments, the foregoing process in which the computer device fits the photoresist model based on the plurality of first parameter groups and the plurality of reference photoresist pattern matrixes to obtain coefficients of the plurality of photoresist items in the photoresist model includes the following operations. The computer device performs least square fitting on the photoresist model based on the plurality of first parameter groups and the plurality of reference photoresist pattern matrixes to obtain coefficients of the plurality of photoresist items. In this exemplary embodiment of this disclosure, the least square fitting is performed through the reference photoresist pattern matrix to obtain a coefficient in the photoresist model. Because the reference photoresist pattern matrix has good reality, the coefficient with high accuracy can be obtained by fitting.

In some exemplary embodiments, the computer device performs fitting by using a least square method with a constraint condition. The constraint condition refers to defining a range of a coefficient of each photoresist item. For example, in the formula (1), absolute values of coefficients of the first photoresist item and the second photoresist item are not greater than 5, and absolute values of coefficients of the third photoresist item and the fourth photoresist item are not greater than 1. The least square method with the constraint condition can satisfy a constraint on each coefficient.

In this exemplary embodiment of this disclosure, one reference photoresist pattern matrix corresponds to one light intensity distribution. For each first parameter group, the computer device substitutes the first parameter group, one reference photoresist pattern matrix, and the light intensity corresponding to the reference photoresist pattern matrix into the photoresist model to obtain a photoresist model with a coefficient to be determined. Similarly, each reference photoresist pattern matrix and the light intensity corresponding to the reference photoresist pattern matrix are substituted into the photoresist model to obtain a photoresist model with a plurality of coefficients to be determined corresponding to the first parameter group. Then, the least square fitting with the constraint condition is performed based on the photoresist model with the plurality of coefficients to be determined respectively corresponding to the plurality of first parameter groups to obtain the plurality of coefficients.

304: The computer device determines predicted photoresist pattern matrixes of the plurality of first parameter groups based on the photoresist model with the determined coefficients and the plurality of first parameter groups.

In this exemplary embodiment of this disclosure, the computer device substitutes the coefficients of the plurality of photoresist items into the photoresist model to obtain the photoresist model with the determined coefficients. For each first parameter group, the computer device substitutes the first parameter group into the photoresist model with the determined coefficients, and solves the photoresist model to obtain the predicted photoresist pattern matrix of the first parameter group. That is, the predicted photoresist pattern matrix of each first parameter group is obtained through the foregoing formulas (1) and (2).

305: The computer device establishes a Gaussian process model based on the plurality of first parameter groups and errors respectively corresponding to the plurality of first parameter groups to obtain a mean function and a kernel function in the Gaussian process model, the mean function and the kernel function being configured for predicting, based on the parameter group, an error corresponding to the parameter group, and an error corresponding to each first parameter group being a difference between a predicted photoresist pattern matrix of the first parameter group and a plurality of reference photoresist pattern matrixes.

In this exemplary embodiment of this disclosure, the Gaussian process model establishes a mapping relationship between the parameter group and the error. The Gaussian process may be described as Error(x)˜GP(μ(x), σ(x)), Error(x) represents an error, μ(x) represents a mean function, σ(x) represents a kernel function, and x represents any parameter group. The Gaussian process model is a set of random variables satisfying a joint Gaussian distribution, and an overall root-mean-square error of the first parameter group set is described by using the Gaussian process model. μ(x) and σ(x) are respectively configured for describing a mean value and uncertainty of the plurality of parameter groups in the first parameter group set. The computer device establishes the Gaussian process model through a Gaussian process regression algorithm. The Gaussian process regression algorithm is a non-parameter regression algorithm and aims at establishing a function distribution consistent with the first parameter group set.

In some exemplary embodiments, a process of determining the error corresponding to each parameter group includes the following operations: for each first parameter group in the first parameter group set, the computer device determines differences between the predicted photoresist pattern matrix of the first parameter group and the plurality of reference photoresist pattern matrixes; and the computer device uses a root-mean-square error among a plurality of differences as the error corresponding to the first parameter group, where the plurality of differences are differences between the predicted photoresist pattern matrix of the first parameter group and the plurality of reference photoresist pattern matrixes. In this exemplary embodiment of this disclosure, the error corresponding to the first parameter group is a root-mean-square error among a plurality of errors, so that accuracy of the error corresponding to each parameter group is high.

306: The computer device determines, for each second parameter group based on the mean function and the kernel function, a mean value and a kernel function value that correspond to the second parameter group, and determines, based on the mean value and the kernel function value corresponding to the second parameter group, an expected value corresponding to the second parameter group, the second parameter group being a parameter group other than the first parameter group in the candidate parameter group set.

In some exemplary embodiments, the computer device determines the expected value through an expected improvement function. For example, for the expected improvement function, refer to the following formula (4).

$$EI ( x ) = σ ( x ) [ z Φ ( z ) + φ ( z ) ] , z = ( {f}^{min} - μ ( x ) ) / σ ( x ) ; \qquad ( 4 )$$

where EI(x) represents an expected value, z represents an intermediate parameter, Φ(z) represents an accumulated density function of a normal distribution function, φ(z) represents a probability density function of the normal distribution function, and f^{min} represents a minimum error corresponding to a parameter group in a current first parameter group set. A first term (σ(x)zΦ(z)) in the formula (4) tends to find a result better than a current optimal value, indicating a local area search process. The second term (σ(x)φ(z)) in the formula (4) tends to find that the second parameter group has a region with higher uncertainty, indicating a global search process. In this exemplary embodiment, local optimization and global search can be better considered based on the expected improvement function, and then a parameter group with a high optimization value can be found based on the obtained expected value.

In some exemplary embodiments, the computer device uses an n-dimensional square exponential function as the kernel function, where n is an integer greater than 0, for example, referring to the kernel function shown in the following formula (5).

$$k ( x , {x}^{′} ) = exp \{ - \frac{{\sum }_{i = 1}^{n} {\vert {x}_{i} - {x}_{i}^{′} \vert}^{2}}{{σ}_{i}^{2}} \} ; \qquad ( 5 )$$

where k(x, x′) represents the kernel function value, x and x′ represent two different parameter groups, xᵢ represents an i^{th} parameter in a parameter group set x, n represents a dimension of x, and σᵢ² of represents a hyper-parameter obtained through maximum likelihood estimation.

In this exemplary embodiment of this disclosure, a process of predicting expected values of the plurality of second parameter groups in the candidate parameter group set based on the plurality of first parameter groups and the errors respectively corresponding to the plurality of first parameter groups is implemented through the foregoing operations 305 to 306. In this exemplary embodiment, a mapping relationship between the parameter group and the error is established through a Gaussian process model of Bayesian active learning. A parameter group that can effectively optimize the photoresist model is determined based on a function in the mapping relationship, so that the parameter group that can effectively optimize the photoresist model can be found, thereby improving efficiency and accuracy of optimizing the photoresist model. Optionally, the second parameter group is stored in a remaining parameter group set.

The foregoing operations 305 to 306 are merely an optional implementation of determining the expected value. In this exemplary embodiment of this disclosure, the expected value can alternatively be determined through another optional implementation. This is not specifically limited herein. For example, the error corresponding to the parameter group is directly determined based on the Gaussian process model, the error is used as the expected value, and correspondingly, the parameter group corresponding to a small error is added to the first parameter group set.

307: The computer device adds a second parameter group with the expected value satisfying a target condition in the plurality of second parameter groups to the first parameter group set to obtain an updated first parameter group set, and respectively assigns, in a case that a current iteration process satisfies an iteration stop condition, a plurality of candidate values in the parameter group having a minimum error in the updated first parameter group set to a plurality of parameters in the photoresist model.

In this exemplary embodiment of this disclosure, the foregoing process in which the computer device adds the second parameter group with the expected value satisfying a target condition in the plurality of second parameter groups to the first parameter group set includes the following two implementations. In an implementation, the computer device adds a second parameter group with the expected value sorted in a first target digit in the plurality of second parameter groups to the first parameter group set. In another implementation, the computer device adds a second parameter group with the expected value greater than a preset expected value in the plurality of second parameter groups to the first parameter group set. Both of the two implementations implement that a second parameter group having a large expected value is added to the first parameter group set, and the second parameter group having the large expected value has high degree of optimization for the photoresist model. In this way, the photoresist model can be effectively optimized based on the second parameter group added to the first parameter group set, thereby obtaining the photoresist model with high accuracy.

In some exemplary embodiments, the computer device directly and respectively assigns the plurality of candidate values in the parameter group corresponding to the minimum error in the first parameter group set obtained in the current iteration to the plurality of parameters in the photoresist model. In some other exemplary embodiments, the computer device compares the minimum error corresponding to the parameter group in the first parameter group set obtained in the current iteration with the minimum error corresponding to a parameter group in the first parameter group set obtained in a previous iteration, and in a case that the minimum error corresponding to the parameter group in the first parameter group set obtained in the current iteration is less than or equal to the minimum error corresponding to the parameter group in the first parameter group set obtained in the previous iteration, performs the operation of respectively assigning the plurality of candidate values in the parameter group corresponding to the minimum error in the first parameter group set obtained in the current iteration to the plurality of parameters in the photoresist model. In a case that the minimum error corresponding to the parameter group in the first parameter group set obtained in the current iteration is greater than the minimum error corresponding to the parameter group in the first parameter group set obtained in the previous iteration, the plurality of candidate values in the parameter group corresponding to the minimum error in the first parameter group set obtained in the previous iteration are respectively assigned to the plurality of parameters in the photoresist model. The photoresist model obtained in this way can predict a photoresist pattern closest to the reference photoresist pattern, that is, the photoresist model with higher accuracy can be obtained.

The exemplary embodiments of this disclosure provide a method for determining a photoresist model for generating a photoresist pattern. In the method, a predicted photoresist pattern matrix of an existing parameter group in a first parameter group set is determined through the photoresist model, and then degree of optimization of the second parameter group for the photoresist model is predicted based on an error between the predicted photoresist pattern matrix and a reference photoresist pattern matrix, so that a parameter group having good optimization degree in the second parameter groups can be selected to be added to the first parameter group set. According to the method, the first parameter group set is determined iteratively, and in a case that a data volume in the first parameter group set is ensured, a parameter group which can effectively optimize a photoresist model can be found from the first parameter group set, thereby obtaining the photoresist model that can accurately predict a photoresist pattern. In addition, according to the method, a coefficient of the photoresist model is obtained by fitting the parameter group and the reference photoresist pattern, that is, the parameter and the coefficient of the photoresist model are optimized collaboratively, thereby improving accuracy of the photoresist model while ensuring optimization efficiency.

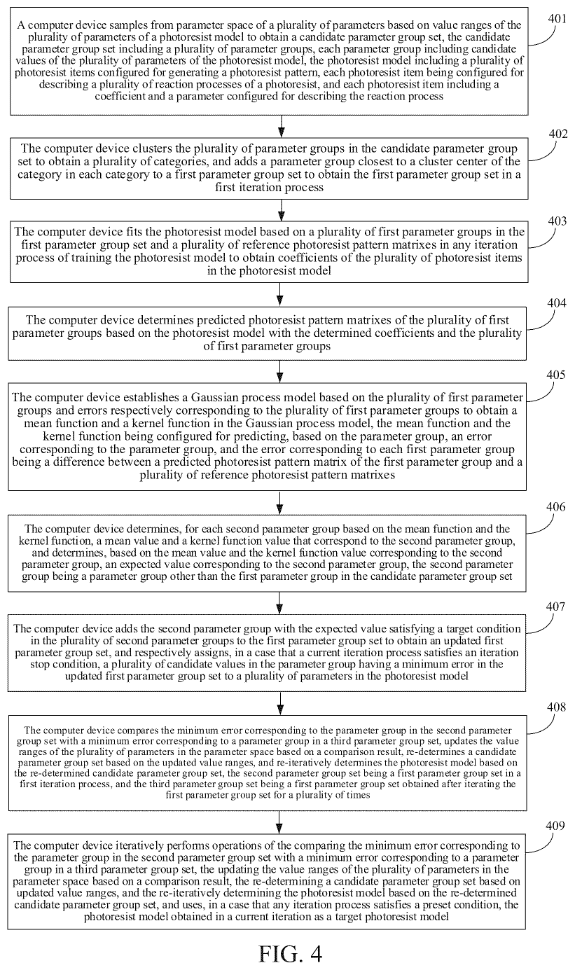

FIG. 3 describes a process of determining a photoresist model. In this process, a plurality of parameters corresponds to a value range, sampling is performed in parameter space once to obtain a candidate parameter group set, and iterative training is performed based on the candidate parameter group set obtained at this time, thereby determining the photoresist model. The following describes another process of determining a photoresist model based on FIG. 4. In this process, a value range of a plurality of parameters are iteratively adjusted, sampling is performed for a plurality of times based on the adjusted value range to iteratively update a candidate parameter group set, and the photoresist model is determined based on an updated candidate parameter group set. FIG. 4 is a flowchart of another method for determining a photoresist model for generating a photoresist pattern according to an exemplary embodiment of this disclosure. The method is performed by the computer device. The method includes the following operations.

401: A computer device samples from parameter space of a plurality of parameters based on value ranges of the plurality of parameters of a photoresist model to obtain a candidate parameter group set, the candidate parameter group set including a plurality of parameter groups, each parameter group including candidate values of the plurality of parameters of the photoresist model, the photoresist model including a plurality of photoresist items configured for generating a photoresist pattern, each photoresist item being configured for describing a plurality of reaction processes of a photoresist, and each photoresist item including a coefficient and a parameter configured for describing the reaction process.

402: The computer device clusters the plurality of parameter groups in the candidate parameter group set to obtain a plurality of categories, and adds a parameter group closest to a cluster center of the category in each category to a first parameter group set to obtain a first parameter group set in a first iteration process.

403: The computer device fits the photoresist model based on a plurality of first parameter groups in the first parameter group set and a plurality of reference photoresist pattern matrixes in any iteration process of training the photoresist model to obtain coefficients of the plurality of photoresist items in the photoresist model.

404: The computer device determines predicted photoresist pattern matrixes of the plurality of first parameter groups based on the photoresist model with the determined coefficients and the plurality of first parameter groups.

405: The computer device establishes a Gaussian process model based on the plurality of first parameter groups and errors respectively corresponding to the plurality of first parameter groups to obtain a mean function and a kernel function in the Gaussian process model, the mean function and the kernel function being configured for predicting, based on the parameter group, an error corresponding to the parameter group, and the error corresponding to each first parameter group being an error between a predicted photoresist pattern matrix of the first parameter group and a plurality of reference photoresist pattern matrixes.

406: The computer device determines, for each second parameter group based on the mean function and the kernel function, a mean value and a kernel function value that correspond to the second parameter group, and determines, based on the mean value and the kernel function value corresponding to the second parameter group, an expected value corresponding to the second parameter group, the second parameter group being a parameter group other than the first parameter group in the candidate parameter group set.

407: The computer device adds a second parameter group with the expected value satisfying a target condition in the plurality of second parameter groups to the first parameter group set to obtain an updated first parameter group set, and respectively assigns, in a case that a current iteration process satisfies an iteration stop condition, a plurality of candidate values in the parameter group having a minimum error in the updated first parameter group set to a plurality of parameters in the photoresist model.

In this exemplary embodiment of this disclosure, the foregoing operations 401 to 407 are the same as operations 301 to operation 307. Details are not described herein again.

408: The computer device compares the minimum error corresponding to the parameter group in the second parameter group set with a minimum error corresponding to a parameter group in a third parameter group set, updates the value ranges of the plurality of parameters in the parameter space based on a comparison result, re-determines a candidate parameter group set based on updated value ranges, and re-iteratively determines the photoresist model based on the re-determined candidate parameter group set, the second parameter group set being a first parameter group set in a first iteration process, and the third parameter group set being a first parameter group set obtained after iterating the first parameter group set for a plurality of times.

In this exemplary embodiment of this disclosure, the computer device re-determines the candidate parameter group set through operation 401, and re-iteratively determines the photoresist model based on the re-determined candidate parameter group set through operations 402 to 407.

In some exemplary embodiments, the process in which the computer device updates the value ranges of the plurality of parameters in the parameter space based on the comparison result includes the following operations: in a case that the minimum error corresponding to the parameter group in the second parameter group set is less than or equal to the minimum error corresponding to the parameter group in the third parameter group set, the computer device reduces the value ranges of the plurality of parameters in the parameter space according to a preset proportion by using the parameter group corresponding to the minimum error in the second parameter group set as a center; and in a case that the minimum error corresponding to the parameter group in the second parameter group set is greater than the minimum error corresponding to the parameter group in the third parameter group set, the computer device increases the value ranges of the plurality of parameters in the parameter space according to a preset proportion by using the parameter group corresponding to the minimum error in the third parameter group set as a center.

Value ranges of the plurality of parameters in the parameter space may be different. Correspondingly, for each parameter, the computer device reduces the value range of the parameter in the parameter space based on a value of the parameter in a target parameter group according to a preset proportion. The target parameter group is a parameter group corresponding to a minimum error in the second parameter group set or the third parameter group set. In this exemplary embodiment of this disclosure, the preset proportion can be set and modified as required. This is not specifically limited herein. Optionally, the preset proportion is 50%.

In some exemplary embodiments, when reducing or increasing the value range of the parameter, the computer device constrains the value range of the parameter to be within a preset proper range. For example, thresholds of the truncation function max, that is, t₁ and t₂ in the formula (1) are constrained to be within a value range of (0, 1). Standard deviations of the Gaussian distribution function G, that is, δ₁, δ₂, δ₃, δ₄ and the like in the formula (1) are constrained to be greater than a pixel size, that is, a constraint is: δ>λ/(8NA). λ represents a wave length of a light source of the photographing machine. NA represents a numerical aperture of the photographing machine.

In this exemplary embodiment of this disclosure, in a case that the minimum error corresponding to the parameter group in the second parameter group set is greater than or equal to the minimum error corresponding to the parameter group in the third parameter group set, it indicates that an optimal parameter group is not found within the value range of the current parameter space, then a parameter search range is reduced, and the value range of the plurality of parameters is reduced by using the parameter group corresponding to the current minimum error as a center, which is equivalent to reducing a search grid, and can improve a search density to find a better parameter group within the current value range. In a case that the minimum error corresponding to the parameter group in the second parameter group set is less than the minimum error corresponding to the parameter group in the third parameter group set, it indicates that an optimal parameter group is found within the value range of the current parameter space, then the search range can be expanded, and the value range of the plurality of parameters is increased by using the parameter group corresponding to the current minimum error as a center, which is equivalent to expanding a search grid, and can find a better parameter group within a larger value range.

409: The computer device iteratively performs operations of the comparing the minimum error corresponding to the parameter group in the second parameter group set with a minimum error corresponding to a parameter group in a third parameter group set, the updating the value ranges of the plurality of parameters in the parameter space based on a comparison result, the re-determining a candidate parameter group set based on updated value ranges, and the re-iteratively determines the photoresist model based on the re-determined candidate parameter group set, and uses, in a case that any iteration process satisfies a preset condition, the photoresist model obtained in a current iteration as a target photoresist model.

In this exemplary embodiment of this disclosure, that any iteration process satisfies a preset condition refers to that a number of iterations in the iteration process reaches a target number of times or a minimum error obtained in the iteration process reaches an expected error value. The target number of times and the expected error value can be set and modified as required. This is not specifically limited herein.

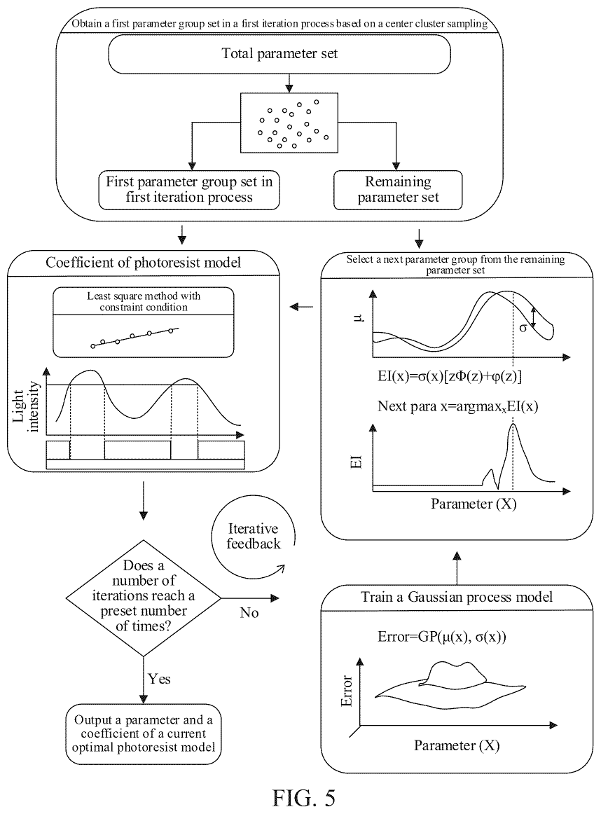

The method for determining a photoresist model for generating a photoresist pattern provided in this exemplary embodiment of this disclosure includes the following operations. First operation: The computer device inputs a photoresist model and a parameter. The computer device inputs a mathematical form of the photoresist model, an initial value range of a plurality of parameters, a preset number of times, a number of iterations, and an expected error value. Second operation: The computer device performs sampling. The computer device performs sampling in parameter space in a hypercubic sampling mode or a random extraction mode. Third operation: The computer device optimizes a photoresist model parameter based on Bayesian active learning of center cluster sampling. For a flowchart that the computer device optimizes the photoresist model parameter based on Bayesian active learning of center cluster sampling, refer to FIG. 5. The process is an iteration process, and includes the following operations: (1) The computer device clusters sampled parameters by using a K-means algorithm, and selects parameter groups corresponding to N cluster centers to form a first parameter group set in a first iteration process. (2) The computer device obtains a coefficient in the photoresist model based on the parameter groups in the first parameter group set in combination with a least square method with a constraint condition. (3) The computer device calculates a root-mean-square error between a predicted photoresist pattern matrix of the plurality of parameter groups obtained through the photoresist model and a reference photoresist pattern matrix. A parameter group corresponding to a current minimum error is output in a case that a number of iterations in any iteration process reaches a preset number of times; and otherwise, operation (4) is performed. (4) The computer device trains a machine learning agent model by using the plurality of parameter groups and root-mean-square errors respectively corresponding to the plurality of parameter groups as a training set, and trains by using a Gaussian process regression algorithm here, to obtain a Gaussian process model. (5) The computer device predicts a second parameter group by using the trained machine learning agent model to obtain a mean value and a kernel function value of the second parameter group, and then obtains an obtaining function. The obtaining function herein is an expected improvement function. The computer device finds parameter groups corresponding to a first target number of maximum obtaining functions in the second parameter group, and adds the parameter groups to the first parameter group set, to obtain the first parameter group set in a next iteration process. (6) The computer device repeatedly performs operation (2). Fourth operation: The computer device scales a grid of parameter space. In a case that the minimum error is not reduced in the third operation, the value range of the plurality of parameters are reduced by half; and otherwise, the value ranges of the plurality of parameters are increased by twice. Then, the third operation is repeatedly performed until the number of iterations reaches a target number of times or the minimum error is less than the expected error value, a parameter group corresponding to the minimum error and the coefficient of the photoresist model are output, and a plurality of values in the parameter group are assigned to a plurality of parameters of the photoresist model to obtain a target photoresist model.

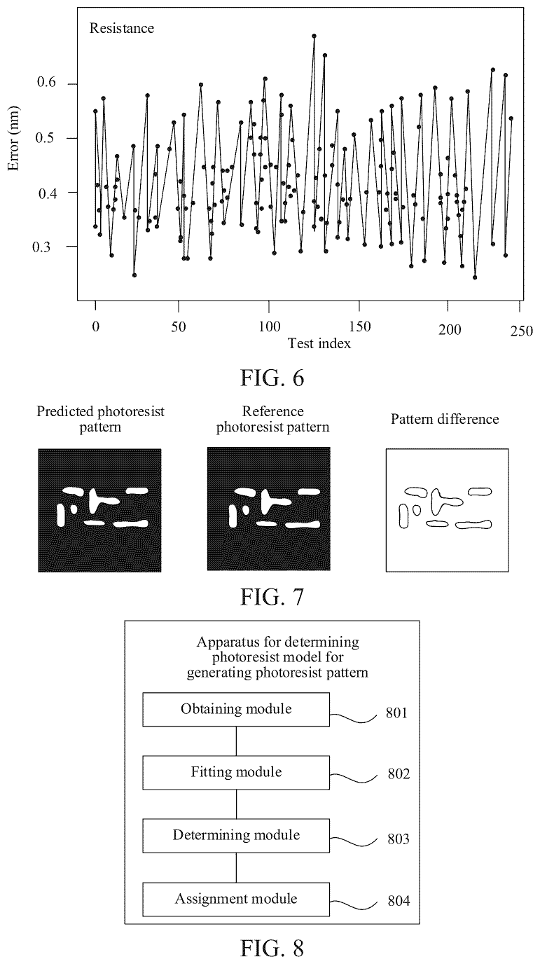

In some exemplary embodiments, the photoresist pattern matrix on a wafer predicted based on the target photoresist model determined by the method according to this exemplary embodiment of this disclosure is compared with the reference photoresist pattern matrix, and a root-mean-square error between the photoresist pattern matrix and the reference photoresist pattern matrix is within a preset error range. For example, FIG. 6 is a schematic diagram of an error of a photoresist pattern matrix according to an exemplary embodiment of this disclosure. An error between a predicted photoresist pattern matrix and a reference photoresist pattern matrix is within 1 nm, that is, an accurate photoresist pattern can be predicted through the photoresist model determined by the method according to the exemplary embodiments of this disclosure.

For another example, FIG. 7 is a comparison diagram between a predicted photoresist pattern and a reference photoresist pattern according to an exemplary embodiment of this disclosure. Three patterns in FIG. 7 are respectively the predicted photoresist pattern, the reference photoresist pattern, and a pattern obtained by making a difference between the two patterns. It can be learned from the figure that the predicted photoresist pattern is almost completely the same as the reference photoresist pattern. The reference photoresist pattern used in this exemplary embodiment of this disclosure is a photoresist pattern of a logic type chip layout in a test set. According to the method according to this exemplary embodiment of this disclosure, a photoresist model is determined, a parameter of an optimal photoresist model can be determined by a relatively low calculation amount, and manual parameter adjustment is almost not needed. That is, the photoresist model with high accuracy can be efficiently obtained by the method according to this exemplary embodiment of this disclosure.

In some exemplary embodiments, to verify the method according to the exemplary embodiments of this disclosure and apply the method to the photoresist model, a widely used public mask data set is selected as data to be used in the exemplary embodiments of this disclosure. The light intensity distribution in the data set is obtained by using an optical model related to a part of an annular light source with a light source of 193 nm, and the reference photoresist pattern is obtained by using a threshold model.

In the method according to the exemplary embodiments of this disclosure, a photoresist model parameter is optimized based on center cluster sampling and a scaling grid Bayesian active learning algorithm, and only a mathematical form of a photoresist model and an initial parameter value need to be input. The method can determine the photoresist model parameter that is globally optimal as much as possible, and further reduce a calculation amount required for modeling, parameter adjustment workload, and a required experimental measurement data amount. The method according to the exemplary embodiments of this disclosure can significantly reduce the calculation amount and the parameter adjustment workload required for optimizing the photoresist model parameter. Further, a number of the photoresist items in the photoresist model can be optimized to further reduce an error of the photoresist model.

In a related technology, in a case that deep learning training is performed based on light intensity distribution and a photoresist pattern to obtain a photoresist model, the accuracy of the photoresist model depends on a data volume. However, measurement data of an exposure pattern on a wafer is usually less and has high costs, making it difficult to put the solution to a place. However, only a coefficient of a photoresist item in the photoresist model can be determined by a lattice-point-dependent error method, and parameters in the photoresist model cannot be optimized. Therefore, a large amount of manual parameter adjustment is still needed. In the method according to the exemplary embodiments of this disclosure, the photoresist model parameter is optimized based on center cluster sampling and a scaling grid Bayesian active learning algorithm. By using a Bayesian active learning machine proxy model, a mapping light of an overall error between experimental data of a parameter group set and reference, and a calculation result of a photoresist model is established, a scaling grid and an iterative sampling policy continuously optimize a photoresist model parameter, and continuously reduce an error. A globally optimal photoresist model parameter can be determined without a large amount of experimental measurement data, a calculation amount can be significantly reduced, and coefficients and parameters in a photoresist model can be cooperatively optimized.

According to the method provided in this exemplary embodiment of this disclosure, in a process of determining a photoresist model, for a coefficient of each photoresist item in the photoresist model and a parameter in each photoresist item, the photoresist is optimized by using Bayesian active learning, and the coefficient of each photoresist item is determined by using a least square method with a constraint condition. For the problem that an optimization algorithm depends on initial value selection, global sampling is performed by using a center cluster sampling method, so that the Bayesian active learning optimization process is more efficient. For a problem that parameter space of parameters to be optimized is exceptionally large, optimization is performed on a coarse grid parameter space by using a scaling grid method, and then, optimization is continuously performed in fine grid parameter space near an extremum, which considers both a calculation amount and optimization efficiency, so that the photoresist pattern obtained by the photoresist model is increasingly close to an experimental measurement pattern. Without a large amount of experimental measurement data, a parameter of the photoresist model can be quickly determined, and a parameter having a minimum experimental measurement data error can be determined, significantly shortening optimization time. Therefore, by the method according to the exemplary embodiments of this disclosure, coefficients and parameters of a photoresist model can be optimized collaboratively, and an optimal photoresist model parameter can be determined with a relatively low calculation amount and relatively high optimization efficiency. In some exemplary embodiments, by the method according to the exemplary embodiments of this disclosure, an electronic design automation (EDA) calculation platform may be carried or combined with mainstream calculation photography software. A chip enterprise inputs a mathematical form of a photoresist model and initial parameter values, and an optimal photoresist model parameter may be obtained by the method according to the exemplary embodiments of this disclosure, thereby significantly shortening calculation time, costs, parameter adjustment workload, and required experimental measurement data volume of the chip enterprise. Th method according to the exemplary embodiments of this disclosure can further be extensively extended and applied to other links of an integrated circuit. For example, the method according to the exemplary embodiments of this disclosure can further be applied to other fields of design and manufacturing, such as optimization of chip yield, optimization of an imaging system of a photographing machine, and optimization of a thermal transport performance of a chip.

FIG. 8 is a block diagram of an apparatus for determining a photoresist model for generating a photoresist pattern according to an exemplary embodiment of this disclosure. The apparatus is configured to perform operations of the foregoing method for determining a photoresist model for generating a photoresist pattern. Referring to FIG. 8, the apparatus includes: an obtaining module 801, configured to obtain a plurality of first parameter groups first parameter group set of a photoresist model in any iteration process of training the photoresist model, the photoresist model including a plurality of photoresist items configured for generating a photoresist pattern, each photoresist item being configured for describing a plurality of reaction processes of a photoresist, each photoresist item including a coefficient and a parameter configured for describing the reaction process, and the first parameter group set being a subset of a candidate parameter group set; a fitting module 802, configure to fit the photoresist model based on the plurality of first parameter groups and a plurality of reference photoresist pattern matrixes to obtain coefficients of the plurality of photoresist items in the photoresist model; a determination module 803, configured to determine the determining predicted photoresist pattern matrixes of the plurality of first parameter groups based on the photoresist model with the determined coefficients and the plurality of first parameter groups, predict expected values of a plurality of second parameter groups in the candidate parameter group set based on the plurality of first parameter groups and errors respectively corresponding to the plurality of first parameter groups, and add a second parameter group with the expected value satisfying a target condition in the plurality of second parameter groups to the first parameter group set to obtain an updated first parameter group set, the expected value being configured to indicate degree of optimization of the photoresist model by the second parameter group, the error corresponding to each parameter group being a difference between the predicted photoresist pattern matrix of the parameter group and the plurality of reference photoresist pattern matrixes, and the second parameter group being a parameter group other than the first parameter group in the candidate parameter group set; and an assignment module 804, configured to respectively assign, in a case that a current iteration process satisfies an iteration stop condition, a plurality of candidate values in the parameter group having a minimum error in the updated first parameter group set to a plurality of parameters in the photoresist model.

In some exemplary embodiments, the determining module 803 is configured to: establish a Gaussian process model based on the plurality of first parameter groups and the errors respectively corresponding to the plurality of first parameter groups to obtain a mean function and a kernel function in the Gaussian process model, the mean function and the kernel function being configured to predict, based on the parameter group, an error corresponding to the parameter group; determine, for each second parameter group based on the mean function and the kernel function, a mean value and a kernel function value that correspond to the second parameter group; and determine the expected value corresponding to the second parameter group based on the mean value and the kernel function value that correspond to the second parameter group.

In some exemplary embodiments, the determining module 803 is configured to: add a second parameter group with the expected value sorted in a first target digit in the plurality of second parameter groups to the first parameter group set.

In some exemplary embodiments, the determining module 803 is configured to: add a second parameter group with the expected value greater than a preset expected value in the plurality of second parameter groups to the first parameter group set.

In some exemplary embodiments, the obtaining module 801 is configured to: cluster the plurality of parameter groups in the candidate parameter group set to obtain a plurality of categories, and add a parameter group closest to a cluster center of the category in each category to a first parameter group set to obtain the first parameter group set in a first iteration process.

In some exemplary embodiments, the fitting module 802 is configured to: perform least square fitting on the photoresist model based on the plurality of first parameter groups and the plurality of reference photoresist pattern matrixes to obtain the coefficients of the plurality of photoresist items.

In some exemplary embodiments, the apparatus further includes: a difference determining module, configured determine, for each first parameter group in the first parameter group set, differences between the predicted photoresist pattern matrix of the first parameter group and the plurality of reference photoresist pattern matrixes; and an error determining module, configured to use root-mean-square errors between a plurality of differences as the errors corresponding to the first parameter group, the plurality of differences being differences between the predicted photoresist pattern matrix of the first parameter group and the plurality of reference photoresist pattern matrixes.

In some exemplary embodiments, the apparatus further includes: a sampling module, configured to sample from parameter space of a plurality of parameters based on value ranges of the plurality of parameters of the photoresist model to obtain the candidate parameter group set.

In some exemplary embodiments, the apparatus further includes: a comparison module, configured to compare a minimum error corresponding to a parameter group in the second parameter group set with a minimum error corresponding to a parameter group in a third parameter group set, update the value ranges of the plurality of parameters in the parameter space based on a comparison result, re-determine a candidate parameter group set based on updated value ranges, and re-iteratively determine the photoresist model based on the re-determined candidate parameter group set, the second parameter group set being a first parameter group set in a first iteration process, and the third parameter group set being a first parameter group set obtained after iterating the first parameter group set for a plurality of times; and an iteration module, configured to iteratively perform operations of comparing a minimum error corresponding to a parameter group in the second parameter group set with a minimum error corresponding to a parameter group in a third parameter group set, updating the value range of the plurality of parameters in the parameter space based on a comparison result, re-determining a candidate parameter group set based on updated value ranges, and re-iteratively determining the photoresist model based on the re-determined candidate parameter group set, and use, in a case that any iteration process satisfies a preset condition, the photoresist model obtained in a current iteration as a target photoresist model.

In some exemplary embodiments, the comparison module is configured to: reduce, in a case that the minimum error corresponding to the parameter group in the second parameter group set is less than or equal to the minimum error corresponding to the parameter group in the third parameter group set, the value ranges of the plurality of parameters in the parameter space according to a preset proportion by using the parameter group corresponding to the minimum error in the second parameter group set as a center; and increase, in a case that the minimum error corresponding to the parameter group in the second parameter group set is greater than the minimum error corresponding to the parameter group in the third parameter group set, the value ranges of the plurality of parameters in the parameter space according to a preset proportion by using the parameter group corresponding to the minimum error in the third parameter group set as a center.

The exemplary embodiments of this disclosure provide an apparatus for determining a photoresist model for generating a photoresist pattern. A predicted photoresist pattern matrix of an existing parameter group in a first parameter group set is determined through the photoresist model, and then degree of optimization of the second parameter group for the photoresist model is predicted based on an error between the predicted photoresist pattern matrix and a reference photoresist pattern matrix, so that a parameter group having good optimization degree in the second parameter groups can be selected to be added to the first parameter group set. In this way, the first parameter group set is determined iteratively, and in a case that a data volume in the first parameter group set is ensured, a parameter group which can effectively optimize a photoresist model can be found from the first parameter group set, thereby obtaining the photoresist model that can accurately predict a photoresist pattern. In addition, according to the method, a coefficient of the photoresist model is obtained by fitting the parameter group and the reference photoresist pattern, that is, the parameter and the coefficient of the photoresist model are optimized collaboratively, thereby improving accuracy of the photoresist model while ensuring optimization efficiency.

In the exemplary embodiments of this disclosure, the computer device can be a terminal or a server. When the computer device is a terminal, the terminal is used as an execution body to implement a technical solution provided in the exemplary embodiments of this disclosure. When the computer device is a server, the server is used as an execution body to implement a technical solution provided in the exemplary embodiments of this disclosure. Or, the technical solution provided in this disclosure is implemented through interaction between the terminal and the server. This is not limited in the exemplary embodiments of this disclosure.

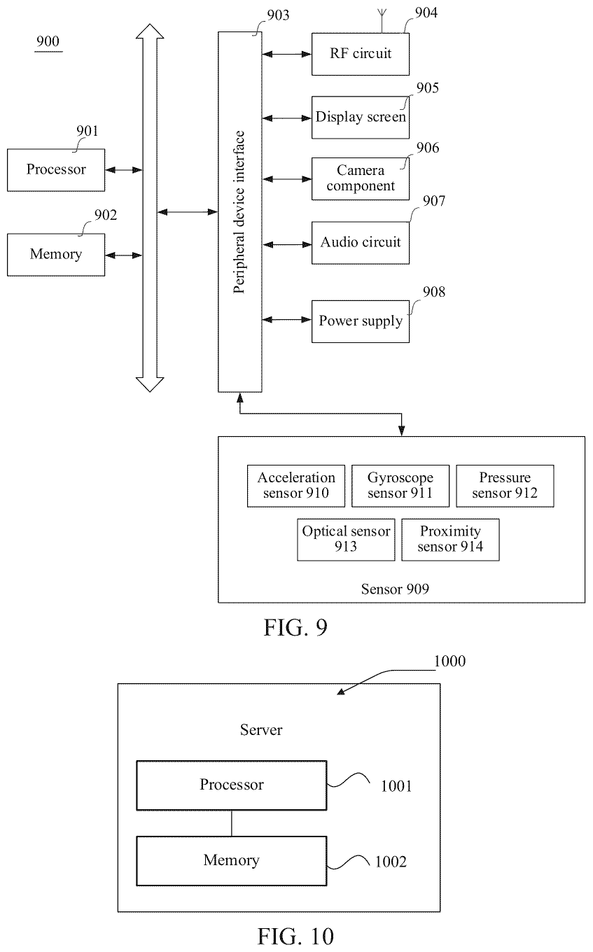

FIG. 9 is a structural block diagram of a terminal 900 according to an exemplary embodiment of this disclosure.

Generally, the terminal 900 includes: a processor 901 and a memory 902.

The processor 901 may include one or more processing cores, for example, a 4-core processor or an 8-core processor. The processor 901 may be implemented in at least one hardware form of a digital signal processor (DSP), a field-programmable gate array (FPGA), and a programmable logic array (PLA). The processor 901 may alternatively include a main processor and a coprocessor. The main processor is a processor configured to process data in an awake state, and is alternatively referred to as a central processing unit (CPU). The coprocessor is a low power consumption processor configured to process the data in a standby state. In some exemplary embodiments, the processor 901 may be integrated with a graphics processing unit (GPU). The GPU is configured to render and draw content that needs to be displayed on a display screen. In some exemplary embodiments, the processor 901 may further include an artificial intelligence (AI) processor. The AI processor is configured to process computing operations related to machine learning.

The memory 902 may include one or more computer-readable storage media. The computer-readable storage medium may be non-transient. The memory 902 may further include a high-speed random access memory and a nonvolatile memory, for example, one or more disk storage devices or flash storage devices. In some exemplary embodiments, a non-transitory computer-readable storage medium in the memory 902 is configured to store at least one computer program, and the at least one computer program is executed by the processor 901 to implement the method for determining a photoresist model for generating a photoresist pattern according to the exemplary embodiments of this disclosure.

In some exemplary embodiments, the terminal 900 further optionally includes: a peripheral device interface 903 and at least one peripheral device. The processor 901, the memory 902, and the peripheral device interface 903 may be connected through a bus or a signal line. Each peripheral device may be connected to the peripheral device interface 903 through a bus, a signal line, or a circuit board. Specifically, the peripheral device includes: at least one of a radio frequency (RF) circuit 904, a display screen 905, a camera component 906, an audio circuit 907, or a power supply 908.

The peripheral interface 903 may be configured to connect the at least one peripheral related to input/output (I/O) to the processor 901 and the memory 902. In some exemplary embodiments, the processor 901, the memory 902, and the peripheral device interface 903 are integrated on a same chip or circuit board. In some other exemplary embodiments, any or two of the processor 901, the memory 902, and the peripheral device interface 903 may be implemented on an independent chip or circuit board. This is not limited in the exemplary embodiments.

The RF circuit 904 is configured to receive and transmit an RF signal, also referred to as an electromagnetic signal. The RF circuit 904 communicates with a communication network and other communication devices through the electromagnetic signal. The RF circuit 904 converts an electric signal into an electromagnetic signal for sending, or converts a received electromagnetic signal into an electric signal. Optionally, the RF circuit 904 includes: an antenna system, an RF transceiver, one or more amplifiers, a tuner, an oscillator, a DSP, an encoding and decoding chipset, a user identity module card, and the like. The RF circuit 904 may communicate with other terminals through at least one wireless communication protocol. The wireless communication protocol includes, but is not limited to: the World Wide Web, a metropolitan area network, the Intranet, various generations of mobile communication networks (2G, 3G, 4G, and 5G), a wireless local area network, and/or a wireless fidelity (Wi-Fi) network. In some exemplary embodiments, the RF 904 may further include a circuit related to near field communication (NFC). This is not limited in this disclosure.

The display screen 905 is configured to display a user interface (UI). The UI may include a pattern, text, an icon, a multimedia resource, and any combination thereof. When the display screen 905 is a touch display screen, the display screen 905 further has a capability of collecting a touch signal on or above a surface of the display screen 905. The touch signal may be input to the processor 901 as a control signal for processing. In this case, the display screen 905 may further be configured to provide a virtual button and/or a virtual keyboard that are/is also referred to as a soft button and/or a soft keyboard. In some exemplary embodiments, one display screen 905 may be arranged on a front panel of the terminal 900. In some other exemplary embodiments, there may be at least two display screens 905 respectively arranged on different surfaces of the terminal 900 or in a folded design. In some other exemplary embodiments, the display screen 905 may be a flexible display arranged on a curved surface or a folded surface of the terminal 900. Even, the display screen 905 may alternatively be arranged in a non-rectangular irregular pattern, that is, a special-shaped screen. The display screen 905 may be prepared by using a material such as a liquid crystal display (LCD), an organic light-emitting diode (OLED), or the like.

The camera component 906 is configured to collect an image or a multimedia resource. Optionally, the camera component 906 includes a front camera and a rear camera. Generally, the front camera is arranged on a front panel of a terminal, and the rear camera is arranged on a back surface of the terminal. In some exemplary embodiments, there are at least two rear cameras, which are respectively any of a main camera, a depth-of-field camera, a wide-angle camera, and a telephoto camera, to achieve background blur through fusion of the main camera and the depth-of-field camera, panoramic photographing and virtual reality (VR) photographing through fusion of the main camera and the wide-angle camera, or other fusion photographing functions. In some exemplary embodiments, the camera component 906 may further include a flash. The flash may be a monochrome temperature flash, or may be a double-color temperature flash. The double color temperature flash refers to a combination of a warm light flash and a cold light flash, and may be used for light compensation under different color temperatures.

The audio circuit 907 may include a microphone and a speaker. The microphone is configured to collect sound waves of a user and an environment, and convert the sound waves into an electrical signal to input to the processor 901 for processing, or input to the RF circuit 904 for implementing voice communication. For the purpose of stereo sound collection or noise reduction, there may be a plurality of microphones, respectively arranged at different parts of the terminal 900. The microphone may further be an array microphone or an omni-directional acquisition type microphone. The speaker is configured to convert the electrical signal from the processor 901 or the RF circuit 904 into sound waves. The speaker may be a conventional film speaker, or may be a piezoelectric ceramic speaker. When the speaker is the piezoelectric ceramic speaker, the speaker not only can convert an electric signal into acoustic waves audible to a human being, but also can convert an electric signal into acoustic waves inaudible to a human being, for ranging and other purposes. In some exemplary embodiments, the audio circuit 907 may further include an earphone jack.

The power supply 908 is configured to supply power to various components in the terminal 900. The power supply 908 may be an alternating current battery, a direct current battery, a primary battery, or a rechargeable battery. When the power supply 908 includes a rechargeable battery, and the rechargeable battery may be a wired rechargeable battery or a wireless rechargeable battery. The wired rechargeable battery is a battery charged through a wired circuit, and the wireless rechargeable battery is a battery charged through a wireless coil. The rechargeable battery may alternatively be configured to support a fast charge technology.

In some exemplary embodiments, the terminal 900 further includes one or more sensors 909. The one or more sensors 909 include, but are not limited to: an acceleration sensor 910, a gyroscope sensor 911, a pressure sensor 912, an optical sensor 913, and a proximity sensor 914.

The acceleration sensor 910 may detect a magnitude of acceleration on three coordinate axes of a coordinate system established with the terminal 900. For example, the acceleration sensor 910 may be configured to detect components of gravity acceleration on the three coordinate axes. The processor 901 may control, according to a gravity acceleration signal collected by the acceleration sensor 910, the display screen 905 to display the user interface in a landscape view or a portrait view. The acceleration sensor 910 may alternatively be configured to collect motion data of a game or a user.

The gyroscope sensor 911 may detect a body direction and a rotation angle of the terminal 900. The gyroscope sensor 911 may cooperate with the acceleration sensor 910 to collect a 3D action by the user on the terminal 900. The processor 901 may implement the following functions according to the data collected by the gyroscope sensor 911: motion sensing (such as changing the UI according to a tilt operation of the user), image stabilization at shooting, game control, and inertial navigation.

The pressure sensor 912 may be arranged at a side frame of the terminal 900 and/or a lower layer of the display screen 905. When the pressure sensor 912 is arranged at the side frame of the terminal 900, a holding signal of the user on the terminal 900 may be detected. The processor 901 performs left and right hand recognition or a quick operation according to the holding signal collected by the pressure sensor 912. When the pressure sensor 912 is arranged on the low layer of the display screen 905, the processor 901 controls, according to a pressure operation of the user on the display screen 905, an operable control on the UI. The operable control includes at least one of a button control, a scroll-bar control, an icon control, and a menu control.

The optical sensor 913 is configured to collect ambient light intensity. In an exemplary embodiment, the processor 901 may control display brightness of the display screen 905 according to the ambient light intensity collected by the optical sensor 913.

Specifically, when the ambient light intensity is relatively high, the display brightness of the display screen 905 is increased; and when the ambient light intensity is relatively low, the display brightness of the display screen 905 is decreased. In another exemplary embodiment, the processor 901 may further dynamically adjust a shooting parameter of the camera component 906 according to the ambient light intensity collected by the optical sensor 913.

The proximity sensor 914, alternatively referred to as a distance sensor, is generally arranged on the front panel of the terminal 900. The proximity sensor 914 is configured to collect a distance between the user and a front surface of the terminal 900. In an exemplary embodiment, when the proximity sensor 914 detects that the distance between the user and the front surface of the terminal 900 gradually decreases, the display screen 905 is controlled by the processor 901 to switch from a screen-on state to a screen-off state. When the proximity sensor 914 detects that the distance between the user and the front surface of the terminal 900 gradually increases, the touch screen 901 is controlled by the display screen 905 to switch from the screen-off state to the screen-on state.

A person skilled in the art may understand that the structure shown in FIG. 9 does not constitute a limitation on the terminal 900, and more or fewer components than those shown in the figure may be included, or some components may be combined, or a different component deployment may be used.

FIG. 10 is a schematic structural diagram of a server according to an exemplary embodiment of this disclosure. A server 1000 may vary considerably depending on configuration or performance, and can include one or more central processing units (CPUs) 1001 and one or more memories 1002. The memory 1002 is configured to store a computer program. The processor 1001 is configured to execute the foregoing computer program to implement the method for determining a photoresist model for generating a photoresist pattern provided in various exemplary embodiments described above. Certainly, the server can further have components such as a wired or wireless network interface, a keyboard, and an I/O interface for inputting and outputting. The server can further include another component for achieving a device function. Details are not described herein.

The exemplary embodiments of this disclosure further provide a computer-readable storage medium. The computer-readable storage medium is configured to store at least one computer program. The at least one computer program is loaded and executed by a processor to implement the method for determining a photoresist model for generating a photoresist pattern according to any implementation described above.

The exemplary embodiments of this disclosure further provide a computer program product. The computer program product includes a computer program. The computer program is stored in a computer-readable storage medium, and a processor of a computer device reads the computer program from the computer-readable storage medium and executes the computer program, to enable the computer device to perform a method for determining a photoresist model for generating a photoresist pattern according to any implementation described above.

In some exemplary embodiments, the computer program product involved in the exemplary embodiments of this disclosure may be deployed on a computer device for execution, or may be executed on a plurality of computer devices located at one location, or may be executed on a plurality of computer devices distributed at a plurality of locations and connected by a communication network. The plurality of computer devices distributed at the plurality of locations and connected by the communication network can form a blockchain system.

The foregoing descriptions are merely optional exemplary embodiments of this disclosure, but are not intended to limit this disclosure. Any modification, equivalent replacement, or improvement made within the spirit and principle of this disclosure fall within the scope of protection of this disclosure.

What is claimed is:

1. A method of determining a photoresist model for generating a photoresist pattern, performed by an electronic device, the method comprising:
obtaining a plurality of first parameter groups from a first parameter group set of a photoresist model in an iterative photoresist model training process, the photoresist model comprising a plurality of photoresist items configured for generating a photoresist pattern, each photoresist item being configured for describing a plurality of reaction processes of a photoresist, each photoresist item comprising a coefficient and a parameter configured for describing the reaction process, and the first parameter group set being a subset of a candidate parameter group set;
fitting the photoresist model based on the plurality of first parameter groups and a plurality of reference photoresist pattern matrixes to obtain coefficients of the plurality of photoresist items in the photoresist model;
determining predicted photoresist pattern matrixes of the plurality of first parameter groups based on the photoresist model with the obtained coefficients and the plurality of first parameter groups, predicting expected values of a plurality of second parameter groups in the candidate parameter group set based on the plurality of first parameter groups and errors respectively corresponding to the plurality of first parameter groups, and adding the second parameter group with the expected value satisfying a target condition in the plurality of second parameter groups to the first parameter group set to obtain an updated first parameter group set, the expected values being configured for indicating a degree of optimization of the second parameter group for the photoresist model, the error corresponding to each parameter group being a difference between the predicted photoresist pattern matrix of the parameter group and the plurality of reference photoresist pattern matrixes, and the second parameter group being a parameter group other than the first parameter group in the candidate parameter group set; and
respectively assigning, when a current iterative process satisfies an iteration stop condition, a plurality of candidate values in the parameter group having a minimum error in the updated first parameter group set to a plurality of parameters in the photoresist model.

2. The method according to claim 1, wherein predicting the expected values of a plurality of second parameter groups in the candidate parameter group set based on the plurality of first parameter groups and errors respectively corresponding to the plurality of first parameter groups comprises:
establishing a Gaussian process model based on the plurality of first parameter groups and the errors respectively corresponding to the plurality of first parameter groups to obtain a mean function and a kernel function in the Gaussian process model, the mean function and the kernel function being configured to predict, based on an input parameter group, an error corresponding to the input parameter group;
determining, for each second parameter group based on the mean function and the kernel function, a mean value and a kernel function value that correspond to the second parameter group; and
determining the expected value corresponding to the second parameter group based on the mean value and the kernel function value that correspond to the second parameter group.

3. The method according to claim 2, wherein adding the second parameter group with the expected value satisfying a target condition in the plurality of second parameter groups to the first parameter group set comprises:
adding a second parameter group with the expected value sorted in a first target digit in the plurality of second parameter groups to the first parameter group set.

4. The method according to claim 2, wherein adding the second parameter group with the expected value satisfying a target condition in the plurality of second parameter groups to the first parameter group set comprises:
adding a second parameter group with the expected value greater than a preset expected value in the plurality of second parameter groups to the first parameter group set.

5. The method according to claim 1, wherein obtaining the first parameter group set in a first iterative process comprises:
clustering the plurality of parameter groups in the candidate parameter group set to obtain a plurality of categories, and adding a parameter group closest to a cluster center of the category in each category to the first parameter group set to obtain the first parameter group set in the first iterative process.

6. The method according to claim 1, wherein fitting the photoresist model based on the plurality of first parameter groups and a plurality of reference photoresist pattern matrixes to obtain coefficients of the plurality of photoresist items in the photoresist model comprises:
performing least square fitting on the photoresist model based on the plurality of first parameter groups and the plurality of reference photoresist pattern matrixes to obtain the coefficients of the plurality of photoresist items.

7. The method according to claim 1, further comprising:
determining, for each first parameter group in the first parameter group set, differences between the predicted photoresist pattern matrix of the first parameter group and the plurality of reference photoresist pattern matrixes; and
using a root-mean-square error among a plurality of differences as the error corresponding to the first parameter group, the plurality of differences being differences between the predicted photoresist pattern matrix of the first parameter group and the plurality of reference photoresist pattern matrixes.

8. The method according to claim 1, further comprising:
sampling from a parameter space of a plurality of parameters of the photoresist model based on value ranges of the plurality of parameters to obtain the candidate parameter group set.

9. The method according to claim 8, wherein after the respectively assigning, when a current iterative process satisfies an iteration stop condition, a plurality of candidate values in the parameter group having a minimum error in the updated first parameter group set to a plurality of parameters in the photoresist model, the method further comprises:
comparing a minimum error corresponding to a parameter group in the second parameter group set with a minimum error corresponding to a parameter group in a third parameter group set, updating the value ranges of the plurality of parameters in the parameter space based on a comparison result, re-determining a candidate parameter group set based on updated value ranges, and re-iteratively determining the photoresist model based on the re-determined candidate parameter group set, the second parameter group set being a first parameter group set in a first iterative process, and the third parameter group set being a first parameter group set obtained after iterating the first parameter group set for a plurality of times; and
iteratively performing operations of comparing a minimum error corresponding to a parameter group in the second parameter group set with a minimum error corresponding to a parameter group in a third parameter group set, updating the value ranges of the plurality of parameters in the parameter space based on a comparison result, re-determining a candidate parameter group set based on updated value ranges, and re-iteratively determining the photoresist model based on the re-determined candidate parameter group set, and using, when an iterative process satisfies a preset condition, the photoresist model obtained in a current iteration as a target photoresist model.

10. The method according to claim 9, wherein updating the value ranges of the plurality of parameters in the parameter space based on a comparison result comprises:
reducing, when the minimum error corresponding to the parameter group in the second parameter group set is less than or equal to the minimum error corresponding to the parameter group in the third parameter group set, the value ranges of the plurality of parameters in the parameter space according to a preset proportion by using the parameter group corresponding to the minimum error in the second parameter group set as a center; and
increasing, when the minimum error corresponding to the parameter group in the second parameter group set is greater than the minimum error corresponding to the parameter group in the third parameter group set, the value ranges of the plurality of parameters in the parameter space according to a preset proportion by using the parameter group corresponding to the minimum error in the third parameter group set as a center.

11. An apparatus for determining a photoresist model for generating a photoresist pattern, the apparatus comprising at least one processor and a memory, the memory having at least one instruction stored therein, and the at least one instruction, when executed by the at least one processor, causing the apparatus being configured to:
obtain a plurality of first parameter groups from a first parameter group set of a photoresist model in an iterative photoresist model training process, the photoresist model comprising a plurality of photoresist items configured for generating a photoresist pattern, each photoresist item being configured for describing a plurality of reaction processes of a photoresist, each photoresist item comprising a coefficient and a parameter configured for describing the reaction process, and the first parameter group set being a subset of a candidate parameter group set;
fit the photoresist model based on the plurality of first parameter groups and a plurality of reference photoresist pattern matrixes to obtain coefficients of the plurality of photoresist items in the photoresist model;
determine predicted photoresist pattern matrixes of the plurality of first parameter groups based on the photoresist model with the obtained coefficients and the plurality of first parameter groups, predict expected values of a plurality of second parameter groups in the candidate parameter group set based on the plurality of first parameter groups and errors respectively corresponding to the plurality of first parameter groups, and add the second parameter group with the expected value satisfying a target condition in the plurality of second parameter groups to the first parameter group set to obtain an updated first parameter group set, the expected values being configured for indicating a degree of optimization of the second parameter group for the photoresist model, the error corresponding to each parameter group being a difference between the predicted photoresist pattern matrix of the parameter group and the plurality of reference photoresist pattern matrixes, and the second parameter group being a parameter group other than the first parameter group in the candidate parameter group set; and
respectively assign, when a current iterative process satisfies an iteration stop condition, a plurality of candidate values in the parameter group having a minimum error in the updated first parameter group set to a plurality of parameters in the photoresist model.

12. The apparatus according to claim 11, wherein the apparatus, when being configured to predict the expected values of a plurality of second parameter groups in the candidate parameter group set based on the plurality of first parameter groups and errors respectively corresponding to the plurality of first parameter groups, is configured by the execution of the at least one instruction to:
establish a Gaussian process model based on the plurality of first parameter groups and the errors respectively corresponding to the plurality of first parameter groups to obtain a mean function and a kernel function in the Gaussian process model, the mean function and the kernel function being configured to predict, based on an input parameter group, an error corresponding to the input parameter group;
determine, for each second parameter group based on the mean function and the kernel function, a mean value and a kernel function value that correspond to the second parameter group; and
determine the expected value corresponding to the second parameter group based on the mean value and the kernel function value that correspond to the second parameter group.

13. The apparatus according to claim 12, wherein the apparatus, when being configured to add the second parameter group with the expected value satisfying a target condition in the plurality of second parameter groups to the first parameter group set, is configured by the execution of the at least one instruction to:
add a second parameter group with the expected value sorted in a first target digit in the plurality of second parameter groups to the first parameter group set.

14. The apparatus according to claim 12, wherein the apparatus, when being configured to add the second parameter group with the expected value satisfying a target condition in the plurality of second parameter groups to the first parameter group set, is configured by the execution of the at least one instruction to:
add a second parameter group with the expected value greater than a preset expected value in the plurality of second parameter groups to the first parameter group set.

15. The apparatus according to claim 11, wherein the apparatus, when being configured to obtain the first parameter group set in a first iterative process, is configured by the execution of the at least one instruction to:
cluster the plurality of parameter groups in the candidate parameter group set to obtain a plurality of categories, and add a parameter group closest to a cluster center of the category in each category to the first parameter group set to obtain the first parameter group set in the first iterative process.

16. The apparatus according to claim 11, wherein the apparatus, when being configured to fit the photoresist model based on the plurality of first parameter groups and a plurality of reference photoresist pattern matrixes to obtain coefficients of the plurality of photoresist items in the photoresist model, is configured by the execution of the at least one instruction to:
perform least square fitting on the photoresist model based on the plurality of first parameter groups and the plurality of reference photoresist pattern matrixes to obtain the coefficients of the plurality of photoresist items.

17. The apparatus according to claim 11, wherein the apparatus is further configured to:
determine, for each first parameter group in the first parameter group set, differences between the predicted photoresist pattern matrix of the first parameter group and the plurality of reference photoresist pattern matrixes; and
use a root-mean-square error among a plurality of differences as the error corresponding to the first parameter group, the plurality of differences being differences between the predicted photoresist pattern matrix of the first parameter group and the plurality of reference photoresist pattern matrixes.

18. The apparatus according to claim 11, wherein the apparatus is further configured to:
sample from a parameter space of a plurality of parameters of the photoresist model based on value ranges of the plurality of parameters to obtain the candidate parameter group set.

19. The apparatus according to claim 18, wherein after the apparatus is configured to respectively assign, when a current iterative process satisfies an iteration stop condition, a plurality of candidate values in the parameter group having a minimum error in the updated first parameter group set to a plurality of parameters in the photoresist model, the apparatus is further configured by the execution of the at least one instruction to:
compare a minimum error corresponding to a parameter group in the second parameter group set with a minimum error corresponding to a parameter group in a third parameter group set, update the value ranges of the plurality of parameters in the parameter space based on a comparison result, re-determine a candidate parameter group set based on updated value ranges, and re-iteratively determine the photoresist model based on the re-determined candidate parameter group set, the second parameter group set being a first parameter group set in a first iterative process, and the third parameter group set being a first parameter group set obtained after iterating the first parameter group set for a plurality of times; and
iteratively perform operations of comparing a minimum error corresponding to a parameter group in the second parameter group set with a minimum error corresponding to a parameter group in a third parameter group set, update the value ranges of the plurality of parameters in the parameter space based on a comparison result, re-determine a candidate parameter group set based on updated value ranges, and re-iteratively determine the photoresist model based on the re-determined candidate parameter group set, and use, when an iterative process satisfies a preset condition, the photoresist model obtained in a current iteration as a target photoresist model.

20. The apparatus according to claim 19, wherein the apparatus, when being further configured to update the value ranges of the plurality of parameters in the parameter space based on a comparison result, is configured by the execution of the at least one instruction to:
reduce, when the minimum error corresponding to the parameter group in the second parameter group set is less than or equal to the minimum error corresponding to the parameter group in the third parameter group set, the value ranges of the plurality of parameters in the parameter space according to a preset proportion by using the parameter group corresponding to the minimum error in the second parameter group set as a center; and
increase, when the minimum error corresponding to the parameter group in the second parameter group set is greater than the minimum error corresponding to the parameter group in the third parameter group set, the value ranges of the plurality of parameters in the parameter space according to a preset proportion by using the parameter group corresponding to the minimum error in the third parameter group set as a center.
